(19) United States
(12) Patent Application Publication
(10) Pub. No.: US 2025/0106982 A1
(43) Pub. Date: Mar. 27, 2025

(54) NANOTWIN LINER FOR THROUGH GLASS VIAS

(71) Applicant: Intel Corporation, Santa Clara, CA (US)

(72) Inventors: Sashi S. KANDANUR, Phoenix, AZ (US); Mitchell PAGE, Mesa, AZ (US); Nicholas S. HAEHN, Scottsdale, AZ (US); Srinivas Venkata Ramanuja PIETAMBARAM, Chandler, AZ (US); Steve S. CHO, Chandler, AZ (US)

(21) Appl. No.: 18/372,585

(22) Filed: Sep. 25, 2023

(51) Int. Cl. H05K 1/02; H01L 21/48; H01L 23/15; H01L 23/498; H05K 1/03; H05K 1/11

(52) U.S. Cl. CPC H05K 1/0271; H01L 21/486; H01L 23/15; H01L 23/49827; H01L 23/49894; H05K 1/0306; H05K 1/116

(57) ABSTRACT

Embodiments disclosed herein include glass cores with through glass vias (TGVs). In an embodiment, an apparatus comprises a solid glass layer with an opening through a thickness of the layer, and a via in the opening. In an embodiment, the via comprises a first portion along sidewalls of the opening, where the first portion has a first microstructure, and a second portion in the opening, where the first portion surrounds the second portion, and where the second portion has a second microstructure that is different than the first microstructure.

### BACKGROUND

Coefficient of thermal expansion (CTE) mismatches between different components within a system can lead to significant integration challenges. Glass substrates for electronics packaging applications may be particularly susceptible to damage or other negative factors that arise from CTE mismatches. For example, conductive vias are formed through the glass substrate in order to provide electrical connections between the top surface and the bottom surface of the substrate. However, the CTE of the via (which is typically copper or a copper alloy) is significantly higher than the CTE of the glass. The CTE of glass may be around 5 parts per million/° C. (ppm/° C.) or less, and the CTE of copper is around 15 ppm/° C. or greater.

During annealing processes or other thermal cycling, the via expands more than the glass. This leads to stress on the glass, which can result in crack propagation. Further, the via may plastically deform during heating, which leads to permanent stress in the glass. Accordingly, glass substrates can exhibit lower mechanical robustness compared to traditional organic package substrates. This leads to lower yields and an increase in overall cost of manufacturing glass substrates suitable for mass production.

### BRIEF DESCRIPTION OF THE DRAWINGS

FIG. 1A is a cross-sectional illustration of a glass substrate with metallic vias, in accordance with an embodiment.

FIG. 1B is a cross-sectional illustration of the glass substrate after stress is induced in the glass substrate due to CTE mismatches, and where the stress results in the formation of a crack in the glass substrate, in accordance with an embodiment.

FIG. 2 is a cross-sectional illustration of a glass substrate with a via that includes a liner surrounding a fill material, in accordance with an embodiment.

FIG. 3A is a schematic illustration of nanotwin grains on opposing sides of a nanotwin boundary, in accordance with an embodiment.

FIG. 3B is an illustration of a microstructure of a via at a boundary between the fill material and the liner, where the liner has a nanotwin microstructure, in accordance with an embodiment.

FIG. 4A is a cross-sectional illustration of a glass substrate with a via that includes a seed layer, a liner, and a fill material, in accordance with an embodiment.

FIG. 4B is a cross-sectional illustration of a glass substrate with a via that includes a buffer, a seed layer, a liner, and a fill material, in accordance with an embodiment.

FIG. 5A is a cross-sectional illustration of a glass substrate, in accordance with an embodiment.

FIG. 5B is a cross-sectional illustration of the glass substrate with a via opening formed through a thickness of the glass substrate, in accordance with an embodiment.

FIG. 5C is a cross-sectional illustration of the glass substrate with a seed layer along sidewalls of the via opening, in accordance with an embodiment.

FIG. 5D is a cross-sectional illustration of the glass substrate after a liner is provided over the seed layer, in accordance with an embodiment.

FIG. 5E is a cross-sectional illustration of the glass substrate after a fill material is disposed in the via opening adjacent to the liner, in accordance with an embodiment.

FIG. 6 is a perspective view illustration of a glass substrate with vias that include a liner and a fill material, in accordance with an embodiment.

FIG. 7A is a cross-sectional illustration of a system that includes a glass interposer with vias that include a liner and a fill material, in accordance with an embodiment.

FIG. 7B is a cross-sectional illustration of a system that includes a package substrate with a glass core and vias, in accordance with an embodiment.

FIG. 8 is a schematic of a computing device built in accordance with an embodiment.

### EMBODIMENTS OF THE PRESENT DISCLOSURE

Described herein are electronic systems, and more particularly, electronic systems with glass substrates that include through glass vias (TGVs) that comprise a liner and a fill material, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

As package substrates advance to smaller feature sizes, larger footprints, and thinner substrates, there has been a drive to enable glass interposer and glass core architectures. Glass substrates have been proposed to replace traditional organic substrate materials due to their improved performance metrics. However, the move to glass substrates is not without issue. One issue to address is associated with coefficient of thermal expansion (CTE) mismatches between materials. Particularly, the CTE of the glass substrate is significantly lower than the CTE of the via material (which is typically copper or a copper alloy). During annealing process, reflow processes, or other thermal cycling, the via may expand more than the glass layer. This can result in stress being applied to the glass layer. In some instances, the via may plastically deform during the heating, and the stress induced in the glass layer can be permanent. The stress can produce cracks or other defects. As such, mechanical and electrical reliability and/or robustness of the glass substrate can be negatively impacted.

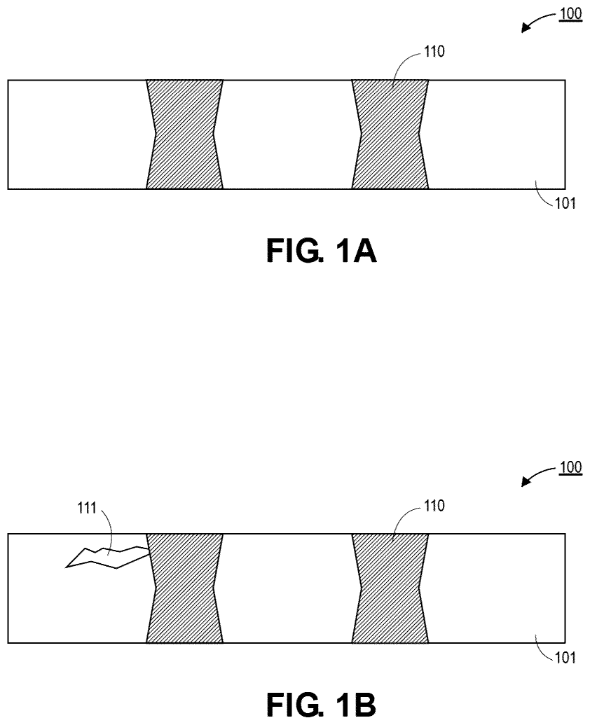

Referring now to FIG. 1A, a cross-sectional illustration of a substrate 100 is shown, in accordance with an embodiment. The substrate 100 may comprise a glass layer 101. The glass layer 101 may be substantially all glass. That is, the glass layer 101 is distinct from a traditional core that includes organic material that is reinforced with glass fibers or the like.

The substrate 100 may include vias 110. The vias 110 may pass through a thickness of the glass layer 101. The vias 110 may be electrically conductive in order to provide electrical coupling between the bottom surface and the top surface of the glass layer 101. The glass layer 101 may include a metallic via 110, such as one comprising copper or a copper alloyed with one or more different elements. The via 110 may have tapered sidewalls. In FIG. 1A, the sidewalls include a double tapered shape that forms an hourglass shaped via 110. Though, a single taper may be provided, or the sidewalls may have a substantially vertical profile.

In the case of a copper or copper alloy via 110, the CTE of the via 110 may be significantly different than the CTE of the glass layer 101. Typically, glass has a CTE between approximately 1 ppm/° C. and approximately 5 ppm/° C. or less, and copper has a CTE of around 16 ppm/° C. Accordingly, the via 110 expands more than the glass layer 101 during thermal cycling. This can result in stress being applied to the glass layer 101. Additionally, heating of the via 110 may result in plastic deformation that provides permanent stress on the glass layer 101. As shown in FIG. 1B, this may result in the formation of cracks 111, or other defects in the glass layer 101. Due to the defects, the glass layer 101 has a decrease in mechanical robustness. This can lead to complete device failures of the substrate 100. Accordingly, yields decrease and costs increase.

One solution that has been proposed is to provide a liner around the vias. The liner may have a low modulus. For example, the liner may comprise a polymer. A low modulus material may be used to reduce stress in glass, because the polymeric liner's low modulus results in lower stresses (for an equivalent strain), than the no polymer-line case, while still accommodating the different strain on either side of itself. However, the use of liners is not without issue. For one, the addition of a liner requires an additional processing operation and additional equipment. Further, the liner further increases the aspect ratio of the opening. This makes the opening harder to fill with copper without forming voids that negatively impact electrical performance and reliability. Accordingly, alternative solutions are desired.

Embodiments disclosed herein provide improved via material engineering in order to reduce or stress applied to the glass through plastic deformation of the via. In some embodiments, the via may comprise a liner and a fill material. As opposed to a polymeric liner, embodiments disclosed herein may include a liner that has the same or similar composition as the fill material. For example, both the liner and the fill material may both comprise substantially all copper or other electrically conductive metallic material or alloy. However, the microstructure of the liner may be different than the microstructure of the fill material. The different microstructure may lead to a liner that has improved mechanical performance compared to the fill material. For example, the liner may have one or more of a higher modulus, higher hardness, higher yield strength, and the like. In the case of yield strength, the higher yield strength may prevent (or minimize) plastic deformation of the via during heating or other thermal cycling. Accordingly residual stress induced into the glass layer from the via is reduced or eliminated. This improves mechanical robustness and increases yield.

In one embodiment, the microstructure of the liner may be described as having a nanotwin microstructure. In the case of a material composition comprising mostly copper, the liner may be described as being nanotwin copper. Though, other electrically conductive materials may also be nanotwinned in some embodiments. A nanotwin microstructure may refer to a material with nanostructural arrangements, where the sub-grain microstructures are considered as twin lamellae. A twin lamella may refer to adjacent grains that have orientations that are mirrored across a grain boundary (i.e., a nanotwin boundary). In a nanotwin microstructure, adjacent nanotwin boundaries may be between 1 nm and 200 nm apart from each other.

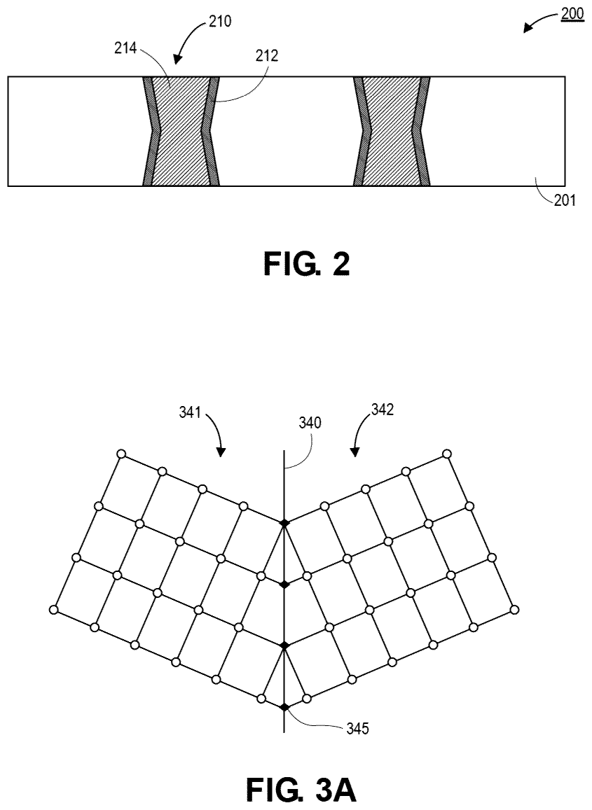

Referring now to FIG. 2, a cross-sectional illustration of a substrate 200 is shown, in accordance with an embodiment. The substrate 200 may be used as an interposer in a packaging architecture. In other embodiments, the substrate 200 may be a core for a package substrate in a packaging architecture. In an embodiment, the substrate 200 may comprise a glass layer 201. The glass layer 201 may be substantially all glass. The glass layer 201 may be a solid material with an amorphous crystal structure. More particularly, the glass layer 201 may be any suitable glass formulation that has the necessary mechanical robustness and compatibility with semiconductor packaging manufacturing and assembly processes. For example, the glass layer 201 may comprise aluminosilicate glass, borosilicate glass, alumino-borosilicate glass, silica, fused silica, or the like. In some embodiments, the glass layer 201 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, and Zn. More generally, the glass layer 201 may comprise silicon and oxygen, as well as any one or more of aluminum, boron, magnesium, calcium, barium, tin, sodium, potassium, strontium, phosphorus, zirconium, lithium, titanium, and zinc. In an embodiment, the glass layer 201 may comprise at least 23 percent silicon (by weight) and at least 26 percent oxygen (by weight). In some embodiments, the glass layer 201 may further comprise at least 5 percent aluminum (by weight). The glass layer 201 may have a thickness that is between approximately 100 μm and approximately 1,000 μm. Though, thinner or thicker glass layers 201 may be used in some embodiments. As used herein, “approximately” may refer to a range of values that are within 10 percent of the stated value. For example, “approximately 100 μm” may refer to a range between 90 μm and 110 μm.

In an embodiment, one or more vias 210 may pass through a thickness of the glass layer 201. The via 210 may be an electrically conductive material in order to provide electrical coupling between a top surface and a bottom surface of the glass layer 201. The via 210 may have any suitable cross-sectional shape. For example, in FIG. 2, the vias 210 have hourglass shaped cross-sections. In other embodiments, the vias 210 may have sidewalls with a single taper, or the sidewalls may be substantially vertical. The vias 210 may have any suitable dimension. For example, a minimum diameter or width of the vias may be between approximately 25 μm and approximately 200 μm. Though, smaller or larger diameters may also be used in some instances.

In an embodiment, the via 210 may comprise a liner 212 and a fill material 214. The liner 212 and the fill material 214 may have an interface that is set in from the outer edge of the via 210. For example, the liner 212 may have a thickness that is between approximately 1 μm and approximately 20 μm. Though, smaller or larger thicknesses may be used for the liner 212. The interface between the fill material 214 and the liner 212 may extend from the top of the via 210 to the bottom of the via 210.

In one embodiment, the via 210 may have a substantially uniform elemental composition. That is, a composition of the liner 212 may be substantially similar to the composition of the fill material 214. In a particular embodiment, the liner 212 and the fill material 214 may both comprise a majority of copper by weight. For example, the liner 212 and the fill material 214 may both comprise at least 80 percent (by weight) copper. Elements in addition to the majority metallic element (e.g., alloying elements, dopants, etc.) may have similar weight percentages between the liner 212 and the fill material 214 in some embodiments. For example, the weight percentage of any element in the liner 212 may be within 1 percent (by weight), within 2 percent (by weight), or within 5 percent (by weight) of the same element in the fill material 214. That is to say, in some embodiments, a simple material composition analysis between the liner 212 and the fill material 214 may not show a substantial difference between the two components. While copper is described as one option for the majority of the elemental composition, it is to be appreciated that other electrically conductive metallic elements may be used as well for the majority element in the via 210. For example, silver may be used in some embodiments. Alloys comprising copper and silver (with other dopant or trace elements) may also be used in some instances.

The difference between the liner 212 and the fill material 214 may be determined by microstructural difference between the liner 212 and the fill material 214. That is, the liner 212 may have a first microstructure, and the fill material 214 may have a second microstructure that is different than the first microstructure. The first microstructure of the liner 212 may be chosen so that one or more mechanical properties of the liner 212 are improved with respect to the corresponding mechanical property of the fill material 214. For example, one or more of a modulus, a hardness, a yield strength, and the like may be higher in the liner 212 compared to that of the fill material 214. The improved mechanical properties reduce plastic deformation of the via 210 during thermal cycling, and can prevent or minimize stress transfer from the via 210 into the glass layer 201. In one embodiment, the yield strength of the liner 212 is approximately five times greater (or more) than the yield strength of the fill material 214.

In a particular embodiment, the improved mechanical properties of the liner 212 may result from a microstructure that is referred to as having a nanotwin microstructure. Nanotwin microstructures allow for improved mechanical properties due to the increased presence of the nanotwin boundaries. With respect to mechanical properties, the nanotwin boundaries function similar to traditional grain boundaries. That is, the nanotwin boundaries impede the movement of dislocations in the crystal lattice. Impeding dislocation movement increases yield strength, hardness, and the like. However, adjacent grains in a non-twin microstructure share crystal lattice points along the nanotwin boundary separating the two grains. As such, electron movement across the nanotwin boundary is not impeded. This allows for the electrical properties of the nanotwin structure to remain substantially the same as those of traditional microstructures. Accordingly, the liner 212 can have an improved mechanical performance (which prevents stress induction in the glass layer 201) while maintaining the electrical performance necessary for high performance via applications.

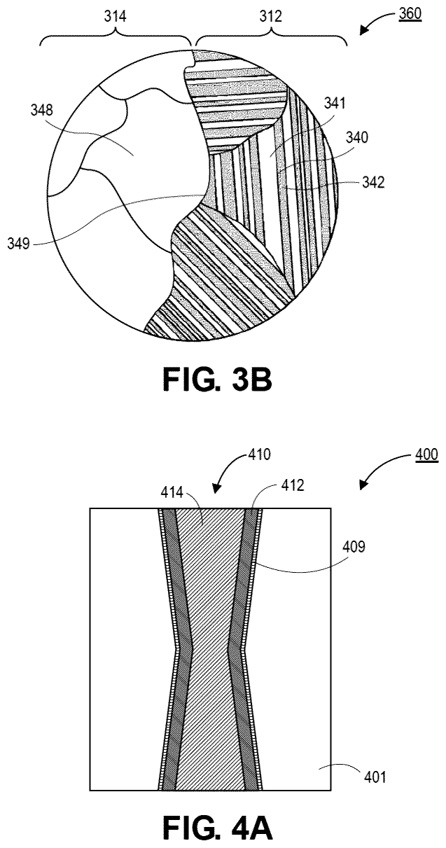

Referring now to FIG. 3A, an illustration of the crystal orientation of a pair of grains 341 and 342 along a boundary 340 for a nanotwin microstructure is shown, in accordance with an embodiment. As shown, the crystal lattice orientation of grain 341 is a mirror image of the crystal lattice orientation of grain 342 across the boundary 340 (i.e., a nanotwin boundary). Further, the grains 341 and 342 share crystal lattice points 345 along the boundary 340.

Referring now to FIG. 3B, an illustration of the microstructure 360 of a via along an interface 349 between the liner 312 (right side) and the fill material 314 (left side) is shown, in accordance with an embodiment. As shown, the interface 349 may not necessarily be a linear boundary (as indicated in FIG. 2). In the fill material 314, larger grains 348 characteristic of traditional deposition processes may be provided. For example, a standard electrodeposition process of copper may result in grain sizes that are larger than the nanotwin grains (e.g., grains 341 and 342) in the liner 312.

The liner 312 may be described as having a nanotwin structure. In some instances, liner 312 may be considered as having a nanotwin microstructure when the nanotwin grains comprise at least 50 percent of the grains along a line from the outer edge of the fill material 314 to an outer edge of the liner 312. In other embodiments, a nanotwin microstructures comprises at least 75 percent nanotwin grains, at least 90 percent nanotwin grains, at least 95 percent nanotwin grains, or at least 99 percent nanotwin grains along a line from the outer edge of the fill material 314 to an outer edge of the liner 312.

As shown, nanotwin grains 341 and 342 may be separated from each other by a nanotwin boundary 340. The nanotwin grains 341 and 342 may sometimes be referred to as sub-grains. For example, three larger grains are shown in the liner 312 of FIG. 3B, and each larger grain has smaller sub-grains 341 and 342. The sub-grains 341 and 342 may present as lamellar structures. For example, the grains 341 and 342 may have a length dimension that is longer than a width dimension. In some instances, the length dimension may be at least twice the width dimension, at least five times the width dimension, at least ten times the width dimension, or at least twenty five times the width dimension.

In some microscopy techniques, the sub-grains 341 and 342 may be shown as having different colors due to their mirrored crystallographic orientations. In an embodiment, adjacent nanotwin boundaries 340 may be spaced apart from each other by 1 nm or more, between 1 nm and 500 nm, or between 5 nm and 200 nm. The spacing between nanotwin boundaries 340 may be non-uniform. In other embodiments, the spacing between nanotwin boundaries 340 may be substantially uniform. In yet another embodiment, the spacing between nanotwin boundaries 340 may have a gradient. For example, the spacing between nanotwin boundaries 340 proximate to the outer edge of the liner 312 may be smaller than the spacing between nanotwin boundaries 340 proximate to the fill material 314.

Referring now to FIG. 4A, a cross-sectional illustration of a substrate 400 is shown, in accordance with an additional embodiment. In an embodiment, the substrate 400 may comprise a glass layer 401. The glass layer 401 may be similar in composition and geometry to any of the glass layers described in greater detail herein. The substrate 400 may be used as a glass interposer or as a glass core for a package substrate.

In an embodiment, a via 410 may be provided through a thickness of the glass layer 401. The via 410 may have any suitable cross-section. For example, an hourglass shaped cross-section is shown in FIG. 4A. Though, other fabrication processes may result in vias 410 with sidewalls that include a single taper or vertical profiles. In an embodiment, the via 410 may comprise a first region (or liner) 412 and a second region (or fill material) 414. Additionally, a seed layer 409 may be provided between the liner 412 and the surface of the glass layer 401. As will be described in greater detail below, the seed layer 409 may be used in order to initiate the plating (e.g., electroplating) of the liner 412 and the fill material 414.

In an embodiment, the liner 412 and the fill material 414 may have a composition and microstructure with similar features described above. Namely, the liner 412 may have a first microstructure, and the fill material 414 may have a second (different) microstructure. At the same time, the elemental composition of the liner 412 and the fill material 414 may be the same or substantially similar in some instances. For example, the liner 412 and the fill material 414 may comprise both copper, silver, or copper and silver (along with one or more other alloying elements, dopant elements, or trace elements).

The first microstructure may be considered a nanotwin microstructure. The nanotwin microstructure of the liner 412 may be similar to any of the nanotwin microstructures described in greater detail above. More generally, when examining the interface between the liner 412 and the fill material 414 with a microscopy technique (e.g., SEM, TEM, etc.), there will be a clear differentiation in one or more of the shape, orientation, and size of the grains on the liner 412 side of the interface and the fill material 414 side of the interface. More particularly, the liner 412 side may have neighboring grains that include mirror image crystal orientations across the grain boundary between the neighboring grains, whereas the fill material 414 may have neighboring grains with random (or at least non-mirror image) crystal orientations with respect to each other.

Referring now to FIG. 4B, a cross-sectional illustration of a substrate 400 is shown, in accordance with an additional embodiment. In an embodiment, the substrate 400 may be similar to the substrate 400 in FIG. 4A, with the addition of a compliant layer 407 between the via 410 and the glass layer 401. The compliant layer 407 may be an additional protection against stress transfer from the via 410 into the glass layer 401. For example, expansion or plastic deformation of the via 410 that arises as a result of thermal cycling or other heating of the substrate 400 can be compensated for by the compliant layer 407. As the via 410 expands and/or plastically deforms, the compliant layer 407 compresses (i.e., reduces in thickness) at a rate required to maintain mechanical equilibrium. With a lower modulus, this results in larger allowable strains in the compliant layer 407, thereby reducing some or all of the stress in the substrate 400.

The compliant layer 407 may be a polymeric material or other low modulus material. The compliant layer 407 may be applied with a deposition process after the via opening through the glass layer 401 is formed. After the compliant layer 407 is formed, the seed layer 409 may be formed along the interior sidewalls of the compliant layer 407. Electroplating processes (such as those described in greater detail below) may then be used in order to plate the via 410 that includes a liner 412 (e.g., a nanotwin liner 412) and a fill material 414.

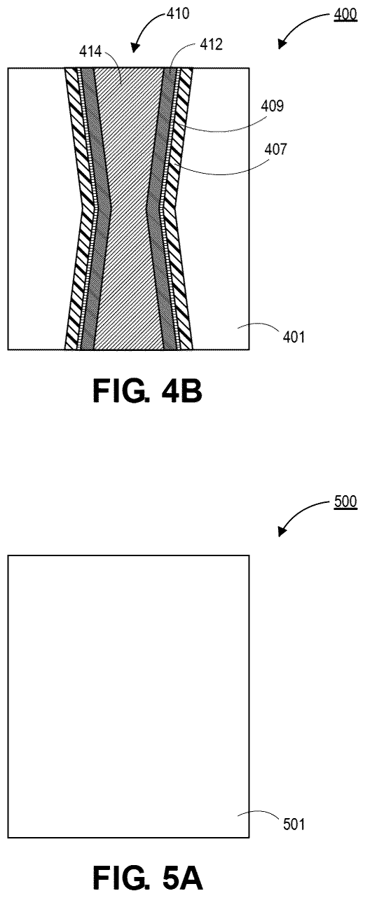

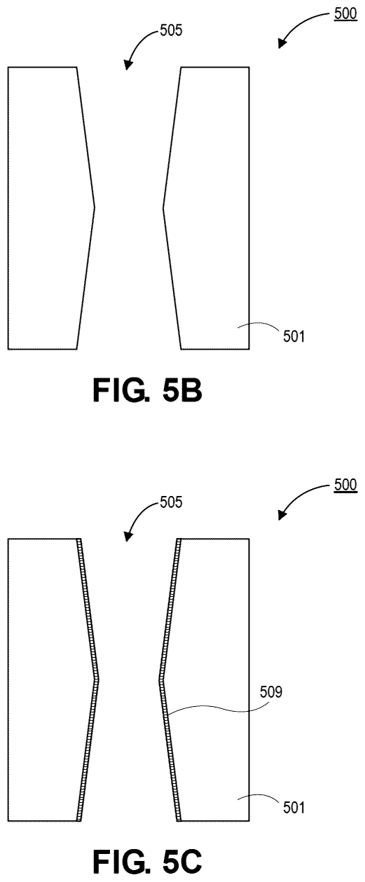

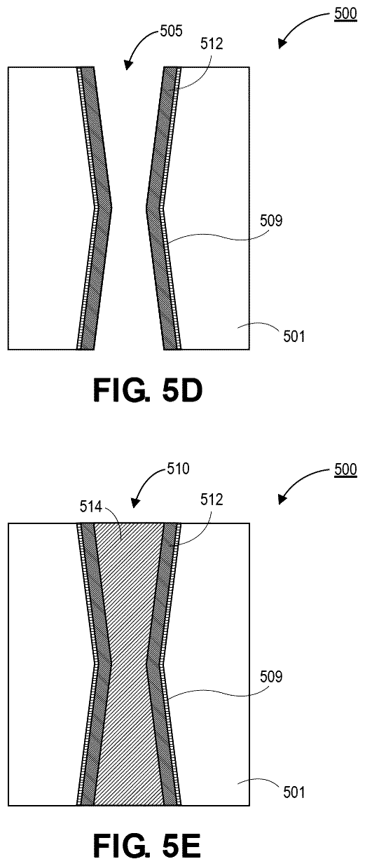

Referring now to FIGS. 5A-5E, a series of cross-sectional illustrations depicting a process for forming a substrate 500 with an electrically conductive via 510 through a glass layer 501 is shown, in accordance with an embodiment.

Referring now to FIG. 5A, a cross-sectional illustration of a substrate 500 with a glass layer 501 is shown, in accordance with an embodiment. In an embodiment, the glass layer 501 may have a composition and geometry similar to any of the glass layers described in greater detail herein. The substrate 500 may be used as part of a glass interposer. In other embodiments, the substrate 500 may be used as a glass core for a package substrate.

Referring now to FIG. 5B, a cross-sectional illustration of the substrate 500 after a via opening 505 is formed through the glass layer 501 is shown, in accordance with an embodiment. The via opening 505 may be formed with any patterning process suitable for use with glass materials. In one embodiment, the via opening 505 may be formed with a laser induced deep etching process or any other suitable laser assisted etching process. Laser assisted etching processes may result in via openings 505 that include tapered sidewalls. In a dual sided approach, a double taper that forms an hourglass shape may be used (as shown in FIG. 5B). Approaches that do not use lasers may also be used in some instances. For example, mechanical drilling, etching (e.g., wet or dry), and the like may be used to form the via opening 505 through the glass layer 501.

Referring now to FIG. 5C, a cross-sectional illustration of the substrate 500 after a seed layer 509 is formed is shown, in accordance with an embodiment. In an embodiment, the seed layer 509 may be formed with any suitable deposition process, such as physical vapor deposition (PVD), chemical vapor deposition (CVD), atomic layer deposition (ALD), electroless deposition, or the like. The seed layer 509 may have a thickness that is between approximately 1 nm and approximately 1 μm. In an embodiment, the seed layer 509 may comprise copper, ruthenium, copper and ruthenium, or any other material that can be used to initiate plating of the via with an electroplating process.

Referring now to FIG. 5D, a cross-sectional illustration of the substrate 500 after the liner 512 is plated on the seed layer 509 is shown, in accordance with an embodiment. In an embodiment, the liner 512 is plated with an electroplating process. Existing electroplating processes have been developed in order to plate metallic nanotwin microstructures, such as nanotwin copper. For example, controls of parameters such as one or more of current density, plating bath chemistry and temperature, continuous or pulsed current, plating duration, and the like can be used in order to tune the microstructure of the liner 512 in order to provide a desired mechanical and electrical performance. In an embodiment, the liner 512 may have a thickness that is between approximately 1 μm and approximately 30 μm.

Referring now to FIG. 5E, a cross-sectional illustration of the substrate 500 after the fill material 514 is plated is shown, in accordance with an embodiment. The fill material 514 may also be plated with an electroplating process. In some embodiments, the fill material 514 may be plated using the same plating bath that was used to plate the liner 512. In other embodiments, the fill material 514 and the liner 512 may be plated in different plating baths. Additionally, the plating parameters used for the fill material 514 may be different than the plating parameters used for the liner 512.

Despite the use of two different sets of plating parameters, the fill material 514 and the liner 512 may include substantially similar material compositions. For example, both the fill material 514 and the liner 512 may comprise substantially all copper with trace amounts of other elements. However, the different plating parameters may result in differences in the microstructures of the fill material 514 and the liner 512. For example, the fill material 514 may have a microstructure that includes grains that have diameters that are larger than those of the grains in the liner 512. Additionally, the grains in the liner 512 may be nanotwin grains and the grains in the fill material 514 may have random crystal orientations. As noted above, certain microscopy techniques (e.g., SEM, TEM, etc.) can be used in order to identify the differences between the grain types of the fill material 514 and the liner 512.

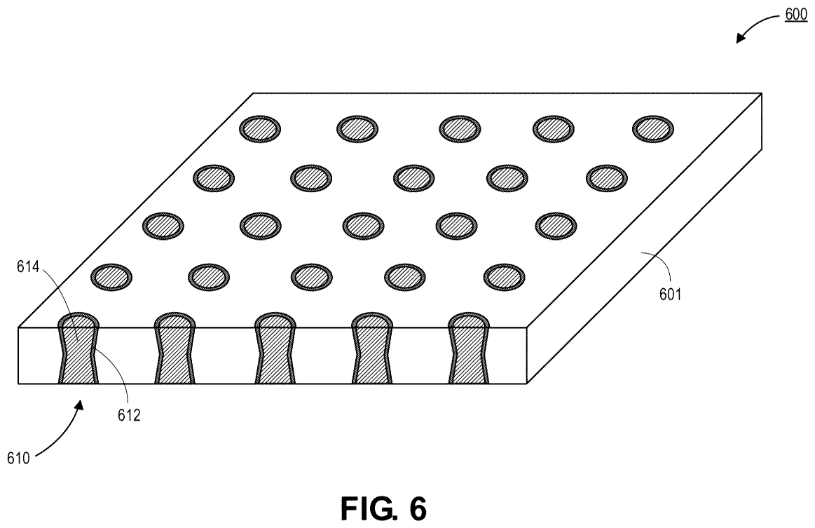

Referring now to FIG. 6, a perspective view illustration of a substrate 600 is shown, in accordance with an embodiment. In an embodiment, the substrate 600 comprises a glass layer 601. The glass layer 601 may have a material composition and geometry similar to any of the glass layers described in greater detail herein. In an embodiment, a plurality of vias 610 may be provided through a thickness of the glass layer 601. The vias 610 may include first regions 612 and second regions 614. The first regions 612 may surround a perimeter of the second regions 614. For example, the first regions 612 may be considered a liner that is formed on the sidewalls of via openings through the glass layer 601, the second regions 614 are fill material that fills the remainder of the via openings.

The vias 610 in FIG. 6 may be substantially similar to any of the via architectures described in greater detail above. For example, the first regions 612 may include a first microstructure, and the second regions 614 may include a second microstructure that is different than the first microstructure. The first microstructure may be engineered to provide improved mechanical properties to the via 610. For example, the first regions 612 may have a higher yield strength than the second regions 614. This is particularly beneficial since it limits the plastic deformation that may otherwise transfer stress into the glass layer 601. This provides for a more robust and mechanically reliable substrate 600.

In an embodiment, the first microstructure is a nanotwin microstructure. The nanotwin architecture of the first regions 612 may be similar to any of the nanotwin microstructures described in greater detail herein. For example, the grains may be lamellar type grains. Further, adjacent grains may have crystallographic orientations that are mirror images of each other across a grain boundary (i.e., a nanotwin boundary). The grain size, grain boundary density, and percentage of nanotwin grains in the first regions 612 may be controlled in order to provide a particular mechanical performance for the vias 610.

The vias 610 in FIG. 6 are arranged in a grid like pattern. However, it is to be appreciated that the vias 610 may be provided in any pattern suitable for a given purpose. Further, while shown as having hourglass shaped cross-sections and circular shapes in the plan view, other cross-sections and shapes may be used. For example, different via hole patterning processes may lead to the formation of different via cross-sections.

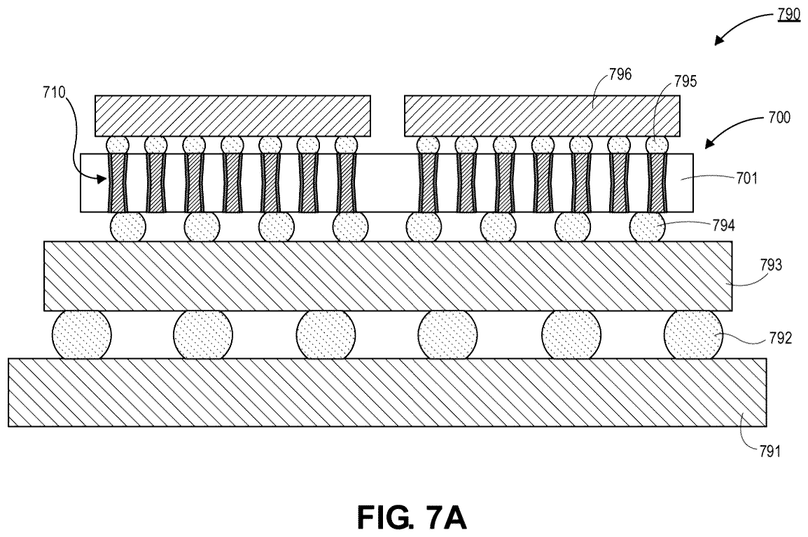

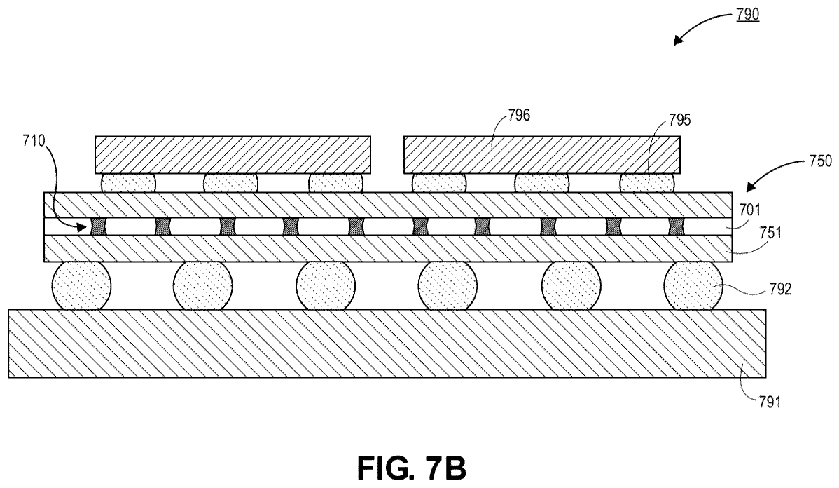

Referring now to FIG. 7A, a cross-sectional illustration of an electronic system 790 is shown, in accordance with an embodiment. In an embodiment, the electronic system 790 may include a board 791, such as a printed circuit board (PCB). The board 791 may be coupled to a package substrate 793 by interconnects 792. The interconnects 792 may include solder balls, pins, or any other suitable interconnect architecture. The package substrate 793 may be an organic package substrate (with or without a core). The package substrate 793 may include electrically conductive routing (not shown) such as pads, vias, traces, etc.

In an embodiment, the package substrate 793 is coupled to an interposer 700 by interconnects 794, such as solder balls or the like. In FIG. 7A, the interconnects 794 do not align with the vias 710. Though, it is to be appreciated that redistribution layers (i.e., pitch scaling layers) may be included as part of the interposer 700 to couple the vias 710 to the interconnects 794. In an embodiment, the interposer 700 may comprise a glass layer 701. The glass layer 701 may have a composition and geometry similar to any of the glass substrates described in greater detail herein. Vias 710 may be provided through a thickness of the glass layer 701. The vias 710 may comprise a liner and a fill material that are similar in structure and composition to any of the vias described in greater detail herein. For example, the liner may include a nanotwin microstructure that is different from the microstructure of the fill material. In some instances, the fill material and the liner may have similar or the same elemental composition (e.g., substantially all copper).

In an embodiment, one or more dies 796 are coupled to the interposer 700 by interconnects 795. The interconnects 795 may include any first level interconnect (FLI) architecture, such as solder bumps, copper bumps, hybrid bonding structures, or the like. The dies 796 may include any type of die. For example, the dies 796 may include central processing units (CPUs), graphics processing units (GPUs), XPUs, or any other type of processor. The dies 796 may also comprise memory dies, or any other peripheral die component.

Referring now to FIG. 7B, a cross-sectional illustration of an electronic system 790 is shown, in accordance with an additional embodiment. In an embodiment, the electronic system 790 comprises a board 791, such as a PCB. The board 791 may be coupled to a package substrate 750 by interconnects 792. The package substrate 750 may include a core 701. In an embodiment, the core 701 is a glass core. The glass core 701 may have a material composition and geometry similar to any of the glass substrates described in greater detail herein.

In an embodiment, the glass core 701 may include vias 710. The vias 710 may be similar to any of the via architectures described in greater detail herein. For example, the vias 710 may have a liner and a fill material. The liner may include a nanotwin microstructure that is different than the microstructure of the fill material. In some instances the fill material and the liner may have the same or similar elemental composition (e.g., substantially all copper).

Buildup layers 751 may be provided over and/or under the glass core 701. The buildup layers 751 may be organic material, such as buildup film. Electrically conductive routing (e.g., pads, traces, vias, etc.) may be provided in and/or on the buildup layers 751 in order to provide electrical coupling between components in the electronic system 790.

In an embodiment, one or more dies 796 may be provided over the package substrate 750. The dies 796 may be coupled to the package substrate through interconnects 795, such as any suitable FLI architecture. The dies 796 may be any type of die, such as one of the types described above with respect to FIG. 7A. In an embodiment, two or more dies 796 may be communicatively coupled together through a bridge (not shown). The bridge may be embedded in the package substrate 750 or provided over the package substrate 750.

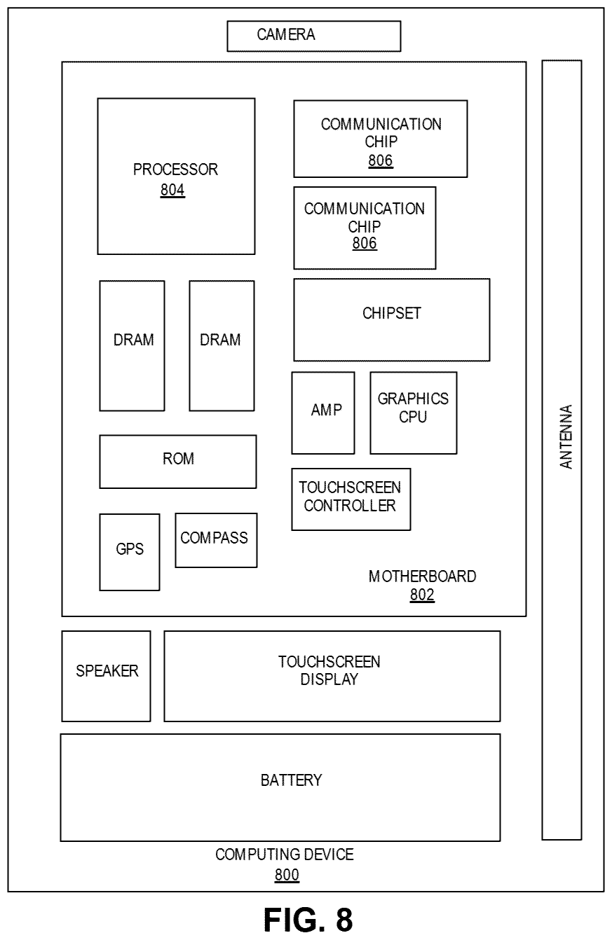

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that includes a glass substrate with a via, wherein the via includes a liner with a nanotwin microstructure and a fill material with a microstructure that is different than that of the liner, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that includes a glass substrate with a via, wherein the via includes a liner with a nanotwin microstructure and a fill material with a microstructure that is different than that of the liner, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a layer, wherein the layer is a solid glass layer; an opening through a thickness of the layer; and a via in the opening, wherein the via comprises: a first portion along sidewalls of the opening, wherein the first portion has a first microstructure; and a second portion in the opening, wherein the first portion surrounds the second portion, and wherein the second portion has a second microstructure that is different than the first microstructure.

Example 2: the apparatus of Example 1, wherein the first portion has a first material composition and the second portion has a second material composition, wherein a majority element by weight of the first material composition is the same as a majority element by weight of the second material composition.

Example 3: the apparatus of Example 2, wherein the first material composition is substantially the same as the second material composition.

Example 4: the apparatus of Examples 1-3, wherein the first microstructure comprises a lamellar structure.

Example 5: the apparatus of Example 4, wherein a first lamellar grain has a first crystal lattice orientation and an immediately adjacent second lamellar grain has a second crystal lattice orientation that is a mirror image of the first crystal lattice orientation across a grain boundary between the first lamellar grain and the second lamellar grain.

Example 6: the apparatus of Example 5, wherein the grain boundary is a nanotwin boundary.

Example 7: the apparatus of Examples 1-6, wherein the first portion of the via has a thickness that is at least 1 μm and up to 30 μm.

Example 8: the apparatus of Examples 1-7, wherein one or more of a modulus, a hardness, and a yield strength of the first portion is greater than a corresponding one or more of a modulus, a hardness, and a yield strength of the second portion.

Example 9: the apparatus of Example 8, wherein the yield strength of the first portion is at least five times the yield strength of the second portion.

Example 10: an apparatus, comprising: a layer, wherein the layer comprises a solid glass substrate; and a via through the layer, wherein the via comprises: a fill material; and a liner around the fill material, wherein the liner comprises at least 50 percent nanotwinned crystal grains along a line from an outer edge of the fill material to an outer edge of the liner.

Example 11: the apparatus of Example 10, wherein the liner comprises at least 90 percent nanotwinned crystal grains along the line from the outer edge of the fill material to the outer edge of the liner.

Example 12: the apparatus of Example 10 or Example 11, comprising a first nanotwin boundary and a second nanotwin boundary adjacent to the first nanotwin boundary, wherein the first nanotwin boundary is between 1 nm and 200 nm away from the second nanotwin boundary.

Example 13: the apparatus of Examples 10-12, wherein the liner has a thickness between 1 μm and 30 μm.

Example 14: the apparatus of Examples 10-13, wherein the liner comprises at least 80 percent by weight copper, and wherein the fill material comprises at least 80 percent by weight copper.

Example 15: the apparatus of Example 14, wherein the liner and the fill material have the same elemental composition to within 2 percent by weight of any element in the liner and the fill material.

Example 16: an apparatus, comprising: a board; an interposer over the board, wherein the interposer comprises: a glass layer; a via through the glass layer, wherein the via comprises an internal interface at least 1 μm away the outer surface of the via, and wherein the internal interface has nanotwinned grains on an outer region and non-twinned grains on an inner region; and a die on the interposer.

Example 17: the apparatus of Example 16, wherein the via comprises copper, and wherein a weight percentage of copper in the outer region of the internal interface and a weight percentage of copper in the inner region of the internal interface are within 2 percent of each other.

Example 18: the apparatus of Example 16 or Example 17, wherein the nanotwinned grains have adjacent nanotwin boundaries that are between 5 nm and 200 nm apart from each other.

Example 19: the apparatus of Examples 16-18, wherein the internal interface is provided from a top of the via to a bottom of the via.

Example 20: the apparatus of Examples 16-19, wherein the apparatus is part of a personal computer, a server, a mobile device, a tablet, or an automobile.

What is claimed is:

1. An apparatus, comprising:
a layer, wherein the layer is a solid glass layer;
an opening through a thickness of the layer; and
a via in the opening, wherein the via comprises:
a first portion along sidewalls of the opening, wherein the first portion has a first microstructure; and
a second portion in the opening, wherein the first portion surrounds the second portion, and wherein the second portion has a second microstructure that is different than the first microstructure.

2. The apparatus of claim 1, wherein the first portion has a first material composition and the second portion has a second material composition, wherein a majority element by weight of the first material composition is the same as a majority element by weight of the second material composition.

3. The apparatus of claim 2, wherein the first material composition is substantially the same as the second material composition.

4. The apparatus of claim 1, wherein the first microstructure comprises a lamellar structure.

5. The apparatus of claim 4, wherein a first lamellar grain has a first crystal lattice orientation and an immediately adjacent second lamellar grain has a second crystal lattice orientation that is a mirror image of the first crystal lattice orientation across a grain boundary between the first lamellar grain and the second lamellar grain.

6. The apparatus of claim 5, wherein the grain boundary is a nanotwin boundary.

7. The apparatus of claim 1, wherein the first portion of the via has a thickness that is at least 1 μm and up to 30 μm.

8. The apparatus of claim 1, wherein one or more of a modulus, a hardness, and a yield strength of the first portion is greater than a corresponding one or more of a modulus, a hardness, and a yield strength of the second portion.

9. The apparatus of claim 8, wherein the yield strength of the first portion is at least five times the yield strength of the second portion.

10. An apparatus, comprising:
a layer, wherein the layer comprises a solid glass substrate; and
a via through the layer, wherein the via comprises:
a fill material; and
a liner around the fill material, wherein the liner comprises at least 50 percent nanotwinned crystal grains along a line from an outer edge of the fill material to an outer edge of the liner.

11. The apparatus of claim 10, wherein the liner comprises at least 90 percent nanotwinned crystal grains along the line from the outer edge of the fill material to the outer edge of the liner.

12. The apparatus of claim 10, comprising a first nanotwin boundary and a second nanotwin boundary adjacent to the first nanotwin boundary, wherein the first nanotwin boundary is between 1 nm and 200 nm away from the second nanotwin boundary.

13. The apparatus of claim 10, wherein the liner has a thickness between 1 μm and 30 μm.

14. The apparatus of claim 10, wherein the liner comprises at least 80 percent by weight copper, and wherein the fill material comprises at least 80 percent by weight copper.

15. The apparatus of claim 14, wherein the liner and the fill material have the same elemental composition to within 2 percent by weight of any element in the liner and the fill material.

16. An apparatus, comprising:
a board;
an interposer over the board, wherein the interposer comprises:
a glass layer;
a via through the glass layer, wherein the via comprises an internal interface at least 1 μm away the outer surface of the via, and wherein the internal interface has nanotwinned grains on an outer region and non-twinned grains on an inner region; and
a die on the interposer.

17. The apparatus of claim 16, wherein the via comprises copper, and wherein a weight percentage of copper in the outer region of the internal interface and a weight percentage of copper in the inner region of the internal interface are within 2 percent of each other.

18. The apparatus of claim 16, wherein the nanotwinned grains have adjacent nanotwin boundaries that are between 5 nm and 200 nm apart from each other.

19. The apparatus of claim 16, wherein the internal interface is provided from a top of the via to a bottom of the via.

20. The apparatus of claim 16, wherein the apparatus is part of a personal computer, a server, a mobile device, a tablet, or an automobile.
